(19) United States
(12) Patent Application Publication
(10) Pub. No.: US 2013/0257634 A1
(43) Pub. Date: Oct. 3, 2013

(54) Data Encoding and Decoding Method and Device

(71) Applicant: NOVATEK MICROELCTRONICS CORP., Hsin-Chu (TW)

(72) Inventors: Yu-Hsiang Wang, Hsinchu City (TW); Po-Hsiang Fang, Hsinchu City (TW)

(73) Assignee: NOVATEK MICROELECTRONICS CORP., Hsin-Chu (TW)

(21) Appl. No.: 13/855,730

(22) Filed: Apr. 3, 2013

(30) Foreign Application Priority Data
Apr. 3, 2012 (TW) 101111828

(51) Int. Cl. H03M 7/40

(52) U.S. Cl. CPC H03M 7/40
USPC 341/67

(57) ABSTRACT

An encoding method includes receiving a first data with a first length; dividing the first data into a plurality of data segments with a first specific length; obtaining at least one compressible data segment composed of identical data values if it exists and at least one uncompressible data segment composed of non-identical data values if it exists from the plurality of data segments; compressing the at least one compressible data segment to obtain at least one compressed data segment with a second specific length; generating an encoding data segment according to quantity and position of the at least one compressed data segment; and combining the at least one compressed data segment, the at least one uncompressible data segment and the encoding data segment to generate a second data with a second length, wherein the second specific length is shorter than the first specific length.

### BACKGROUND OF THE INVENTION

1. Field of the Invention

The present invention relates to a data encoding and decoding method and device, and more particularly, to an encoding and decoding method and device capable of reducing data transmission overhead via compressing consecutive identical data in the data.

2. Description of the Prior Art

In general, a transmitter (TX) and a receiver (RX) not only need to have mechanisms of transmitting/receiving data but also mechanisms of transmitting/receiving clock information, when transmitting the data. When the data is transmitted via a high speed interface, the data intended to be transmitted may be encoded for meeting requirements of increasing signal transmission quality, reducing electromagnetic interference (EMI), providing error correction and saving clock recovery circuit.

For example, an encoding technique of 8B/10B converts 8-bit data into a 10-bit codeword with clock information according to a mapping mechanism. In detail, the 8-bit data will be separated into two parts for performing the mapping, wherein 5 bits of the 8-bit data are mapped to 6-bit data, and the rest 3 bits of the 8-bit data will be mapped to 4-bit data, and then the 6-bit data and the 4-bit data are combined into the 10-bit codeword. In other words, the 8B/10B encoding converts the original 8 bit data into the 10 bit data such that the data is DC-free and an amount of consecutive identical digits (CID) is less than five. Thus, 2 bits (i.e. 20% of the entire data) are wasted during data transmission.

On the other hand, another 64B/66B encoding in the prior art is to add 2 bits in front of a 64-bit data, and a higher data transmission efficiency can be achieved. However, the data in the 64B/66B encoding has opportunity to have consecutive 65 bits of “0” or 65 bits of “1”, which has a negative effect on the data and clock recovery of subsequent decoding operations.

Therefore, it is a common goal in the industry to develop an encoding method capable of adding minimum additional bits, and a length of consecutive identical logical characters in the converted data is not larger than a certain length, to increase encoding quality and reduce data overhead.

### SUMMARY OF THE INVENTION

It is therefore an objective of the present invention to provide a data encoding and decoding method and device.

The present invention discloses an encoding method. The encoding method includes receiving a first data with a first length; dividing the first data into a plurality of data segments with a first specific length; obtaining at least one compressible data segment composed of identical data values and at least one uncompressible data segment composed of non-identical data values from the plurality of data segments; compressing the at least one compressible data segment to obtain at least one compressed data segment with a second specific length; generating an encoding data segment according to quantity and position of the at least one compressed data segment; and combining the at least one compressed data segment, the at least one uncompressible data segment and the encoding data segment to generate a second data with a second length; wherein the second specific length is shorter than the first specific length.

The present invention further discloses an encoding device. The encoding device includes a processor; and a storage device, storing a program code, the program code is utilized for indicating the processor to execute the following steps, receiving a first data with a first length; dividing the first data into a plurality of data segments with a first specific length; obtaining at least one compressible data segment composed of identical data values and at least one uncompressible data segment composed of non-identical data values from the plurality of data segments; compressing the at least one compressible data segment to obtain at least one compressed data segment with a second specific length; generating an encoding data segment according to quantity and position of the at least one compressed data segment; and combining the at least one compressed data segment, the at least one uncompressible data segment and the encoding data segment to generate a second data with a second length; wherein the second specific length is shorter than the first specific length.

The present invention discloses a decoding method. The decoding method includes receiving a second data with a second length; obtaining an encoding data segment of the second data; obtaining at least one compressed data segment with a second specific length and at least one uncompressible data segment with a first specific length from the second data according to the encoding data segment; restoring the at least one compressed data segment to at least one compressible data segment with the first specific length and identical data values; and combining the at least one compressible data segment and the at least one uncompressible data segment with the first specific length, to generate a first data with a first length; wherein the second specific length is shorter than the first specific length.

The present invention further discloses a decoding device. The decoding device includes a processor; and a storage device, storing a program code, the program code is utilized for indicating the processor to execute the following steps, receiving a second data with a second length; obtaining an encoding data segment of the second data; obtaining at least one compressed data segment with a second specific length and at least one uncompressible data segment with a first specific length from the second data according to the encoding data segment; restoring the at least one compressed data segment to at least one compressible data segment with the first specific length and identical data values; and combining the at least one compressible data segment and the at least one uncompressible data segment with the first specific length, to generate a first data with a first length; wherein the second specific length is shorter than the first specific length.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of an encoding process according to an embodiment of the present invention.

FIG. 2 is a schematic diagram of a decoding process according to an embodiment of the present invention.

FIG. 3 is a schematic diagram utilizing the encoding process of FIG. 1 and the decoding process of FIG. 2 in the data.

FIG. 4A is a schematic diagram of an encoding process of an encoding method according to an embodiment of the present invention.

FIG. 4B is a schematic diagram of a decoding process of a decoding method according to an embodiment of the present invention.

FIG. 5 is a schematic diagram of an encoding/decoding device according to an embodiment of the present invention.

### DETAILED DESCRIPTION

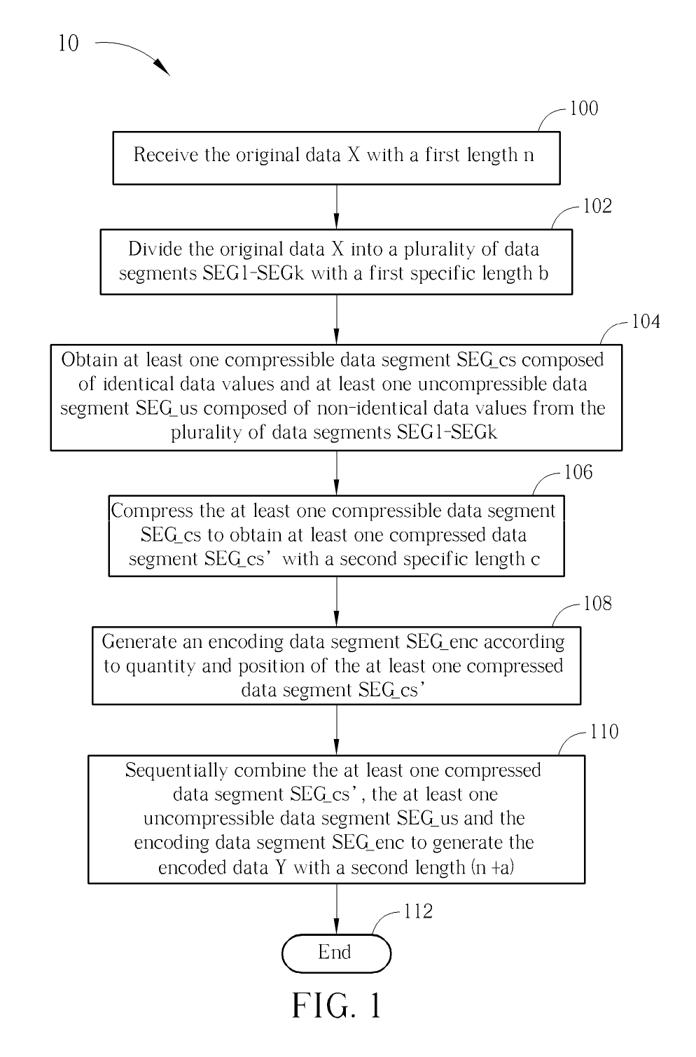

Please refer to FIG. 1, which is a schematic diagram of an encoding process 10 according to an embodiment of the present invention. The encoding process 10 can perform encoding on original data X to obtain encoded data Y, and includes the following steps:

Step 100: Receive the original data X with a first length n.

Step 102: Divide the original data X into a plurality of data segments SEG1-SEGk with a first specific length b.

Step 104: Obtain at least one compressible data segment SEG_cs composed of identical data values (if it exists) and at least one uncompressible data segment SEG_us composed of non-identical data values (if it exists) from the plurality of data segments SEG1-SEGk.

Step 106: Compress the at least one compressible data segment SEG_cs to obtain at least one compressed data segment SEG_cs′ with a second specific length c (if it exists).

Step 108: Generate an encoding data segment SEG_enc according to quantity and position of the at least one compressed data segment SEG_cs′.

Step 110: (Sequentially) combine the at least one compressed data segment SEG_cs′, the at least one uncompressible data segment SEG_us and the encoding data segment SEG_enc to generate the encoded data Y with a second length (n+a).

Step 112: End.

wherein the second specific length c is shorter than the first specific length b.

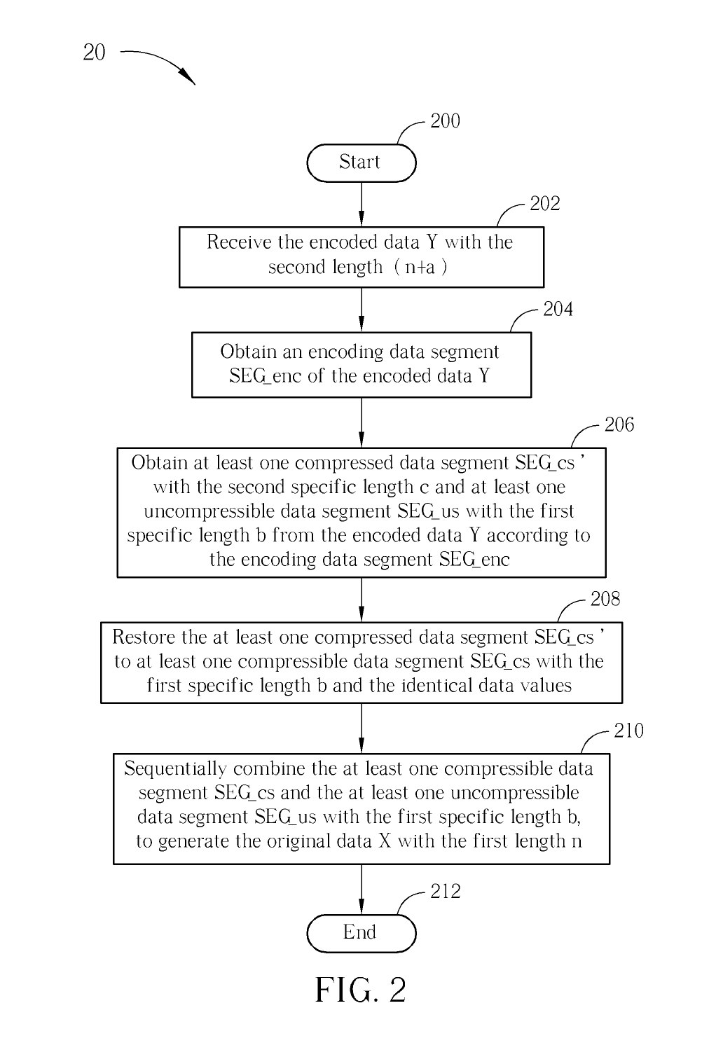

Correspondingly, please refer to FIG. 2, which is a schematic diagram of a decoding process 20 according to an embodiment of the present invention. The decoding process 20 can perform decoding for the encoded data Y obtained from the encoding process 10, to restore the encoded data Y to obtain the original data X, and includes the following steps:

Step 200: Start.

Step 202: Receive the encoded data Y with the second length (n+a).

Step 204: Obtain an encoding data segment SEG_enc of the encoded data Y.

Step 206: Obtain at least one compressed data segment SEG_cs′ with the second specific length c (if it exists) and at least one uncompressible data segment SEG_us with the first specific length b (if it exists) from the encoded data Y according to the encoding data segment SEG_enc.

Step 208: Restore the at least one compressed data segment SEG_cs′ to at least one compressible data segment SEG_cs with the first specific length b and the identical data values (if it exists).

Step 210: (Sequentially) combine the at least one compressible data segment SEG_cs (if it exists) and the at least one uncompressible data segment SEG_us (if it exists) with the first specific length b, to generate the original data X with the first length n.

Step 212: End.

wherein the second specific length c is shorter than the first specific length b.

First, according to the process 10, the present invention first divides the original data X, of which the length is n-bit, into the plurality of data segments SEG1-SEGk, of which the length is b, and then compresses the at least one compressible data segment SEG_cs composed of the identical data values in the plurality of data segments SEG1-SEGk into the at least one compressed data segment SEG_cs′, of which the lengths are shorter. Then, the encoding data segment SEG enc is generated according to the quantity and the position of the at least one compressed data segment SEG_cs′ to indicate the quantity and the position of the at least one compressed data segment SEG_cs′. Then, the at least one compressed data segment SEG_cs′, the at least one uncompressible data segment SEG us and the encoding data segment SEG_enc are combined to generate the encoded data Y of which the total length is (n+a).

Correspondingly, according to the process 20, when performing decoding, the encoding data segment SEG_enc of the encoded data Y, of which the total length is (n+a)-bit, is obtained first, and the at least one compressed data segment SEG_cs′ and the at least one uncompressible data segment SEG_us in the encoded data Y are obtained accordingly. Then, the at least one compressed data segment SEG_cs′ can be restored to the at least one compressible data segment SEG_cs with the identical data values which is further combined with the at least one uncompressible data segment SEG_us to be restored to the original data X.

In short, compared with the conventional encoding method, more additional bits are wasted or long consecutive identical digits are generated during data transmission, causing difficulties to restore clocks or data when decoding, the encoding method of the present invention can effectively utilize a data space saved from compressing the identical digits in the original data, and perform encoding with fewer additional added bits. Thus, overhead of transmission is reduced, and the number of the bits of consecutive 1s or 0s is reduced, such that the transmission is more efficient and the system requirements of the clocks and data recovery circuit in the receiving terminal are relaxed.

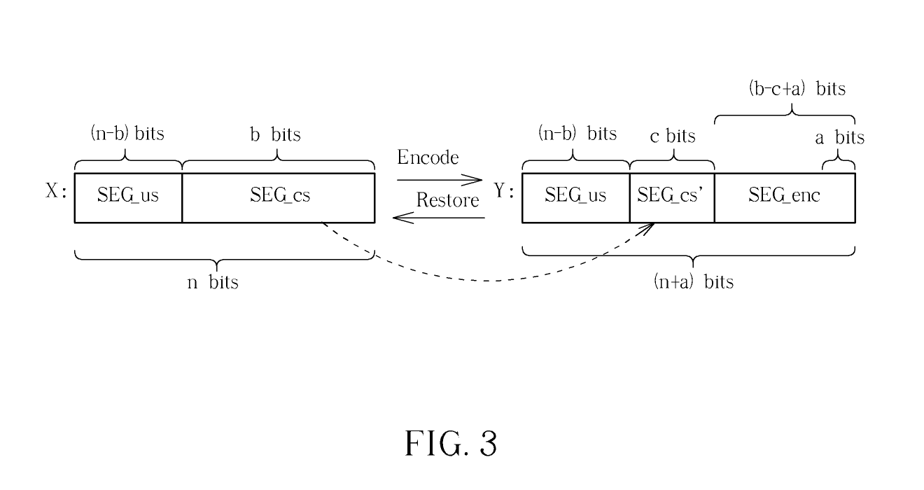

In detail, please refer to FIG. 3, which is a schematic diagram of converting the original data X of which the length is n-bit into the encoded data Y of which the length is (n+a) -bit according to the encoding process 10 in FIG. 1 and the decoding process 20 in FIG. 2. As shown in FIG. 3, when encoding, the original data X includes the uncompressible data segment SEG_us of which the length is (n−b)-bit and one compressible data segment SEG_cs of which the length is b-bit. The compressible data segment SEG_cs can be compressed into one compressed data segment SEG_cs′ of which the length is c-bit. As a result, (b−c) bits can be saved. By adding (a) additional bits in the encoded data Y, (b−c+a) bits can be used for the encoding data segment SEG_enc, to indicate information such as how many compressed data segments SEG_cs′ as well as their positions in the encoded data Y are needed to be restored to the compressible data segment SEG_cs in the original data X in the decoding process. Since (b−c) bits are saved when performing compression in the encoding process according to the present invention, only (a) additional bits, which are fewer than those used in the prior art, are required, such that the cost of transmission is reduced. Note that, FIG. 3 only illustrates an example in which only one compressible data segment SEG_cs is included in the original data X. In practice, the more the compressible data segments are, the more spaces can be reserved for decoding restoring information.

Therefore, segments with repeated “0” or “1” in the original data can be compressed according to the encoding process 10 and the decoding process 20 of FIG. 1 and FIG. 2, to effectively utilize the additional added bits, so as to reduce the overhead of transmission, and also reduce the number of the bits of consecutive 1s or 0s, such that the transmission is more efficient and the system requirements of the clocks and data recovery circuit in the receiving terminal are relaxed. Note that, one of ordinary skill in the art can utilize the encoding process 10 and the decoding process 20 on the data of different lengths, and different dividing methods can also be used, to comply with requirements of different applications.

For example, please refer to Tables 1-1 and 1-2, which are encoding tables utilizing the encoding process 10 shown in FIG. 1 on a 16-bit/17-bit (16B/17B) encoding method. As shown in Tables 1-1 and 1-2, the original data X[0:15] of which the length is 16-bit can be encoded and converted to the encoded data Y[0:16] of which the length is 17-bit (i.e. one additional bit, a=1, is added in the data of 16-bit when encoding). Therefore, as shown in Tables 1-1 and 1-2, an overhead produced by adding the one additional bit in the 16B/17B for performing encoding is only 1/17=5.88% of the encoded data Y[0:16], and at most 7 consecutive identical digits (CID) of 0s or 1s possibly occur.

TABLE 1-1

| Situation | Y0 | Y1 | Y2 | Y3 | Y4 | Y5 | Y6 | Y7 |
|---|---|---|---|---|---|---|---|---|
| 1 | d0 | d1 | d2 | d3 | d4 | d5 | d6 | d7 |
| 2 | d0 | d1 | d2 | d3 | d4 | d5 | d6 | d7 |
| 3 | d0 | d4 | d5 | d6 | d7 | d8 | d9 | d10 |
| 4 | d0 | d1 | d2 | d3 | d4 | d8 | d9 | d10 |
| 5 | d0 | d1 | d2 | d3 | d4 | d5 | d6 | d7 |
| 6 | d0 | d1 | d2 | d3 | d4 | d5 | d6 | d7 |
| 7 | d0 | d0′ | d4 | d8 | d9 | d10 | d11 | d12 |
| 8 | d0 | d0′ | d4 | d5 | d6 | d7 | d8 | d12 |
| 9 | d0 | d0′ | d4 | d5 | d6 | d7 | d8 | d9 |
| 10 | d0 | d1 | d2 | d3 | d4 | d4′ | d8 | d12 |
| 11 | d0 | d1 | d2 | d3 | d4 | d4′ | d8 | d9 |
| 12 | d0 | d1 | d2 | d3 | d4 | d5 | d6 | d7 |
| 13 | d0 | d0′ | d4 | d4′ | d8 | d8′ | d12 | d13 |
| 14 | d0 | d0′ | d4 | d4′ | d8 | d9 | d10 | d11 |
| 15 | d0 | d0′ | d4 | d5 | d6 | d7 | d8 | d8′ |
| 16 | d0 | d1 | d2 | d3 | d4 | d4′ | d8 | d8′ |
| 17 | d0 | d0′ | d4 | d4′ | d8 | d8′ | d12 | d12′ |

TABLE 1-2

| Situa- | | | | | | | | | |
|---|---|---|---|---|---|---|---|---|---|
| tion | Y8 | Y9 | Y10 | Y11 | Y12 | Y13 | Y14 | Y15 | Y16 |
| 1 | d8 | d9 | d10 | d11 | d12 | d13 | d14 | d15 | 0 |
| 2 | d8 | d9 | d10 | d11 | 1 | 1 | 0 | 0 | 1 |
| 3 | d11 | d12 | d13 | d14 | d15 | 0 | 0 | 0 | 1 |
| 4 | d11 | d12 | d13 | d14 | d15 | 0 | 0 | 1 | 1 |
| 5 | d8 | d12 | d13 | d14 | d15 | 0 | 1 | 0 | 1 |
| 6 | d8 | d9 | d10 | d11 | d12 | 0 | 1 | 1 | 1 |
| 7 | d13 | d14 | d15 | 0 | 0 | 1 | 0 | 0 | 1 |
| 8 | d13 | d14 | d15 | 0 | 0 | 1 | 0 | 1 | 1 |
| 9 | d10 | d11 | d12 | 0 | 0 | 1 | 1 | 0 | 1 |
| 10 | d13 | d14 | d15 | 1 | 0 | 1 | 0 | 0 | 1 |
| 11 | d10 | d11 | d12 | 1 | 0 | 1 | 0 | 1 | 1 |
| 12 | d8 | d8′ | d12 | 1 | 0 | 1 | 1 | 0 | 1 |
| 13 | d14 | d15 | 0 | 0 | 1 | 1 | 0 | 1 | 1 |
| 14 | d12 | d12′ | 0 | 0 | 1 | 1 | 1 | 0 | 1 |
| 15 | d12 | d12′ | 1 | 0 | 1 | 1 | 0 | 1 | 1 |
| 16 | d12 | d12′ | 1 | 0 | 1 | 1 | 1 | 0 | 1 |
| 17 | 0 | 1 | 0 | 1 | 1 | 1 | 0 | 1 | 1 |

In Tables 1-1 and 1-2, which list encoding results corresponding to all possible situations of the original data X[0:15] of which the length is 16-bit. Wherein d0-d15 respectively represent the bit values of the original data X[0:15] before encoding, while Y0-Y16 respectively represent the bit values of the encoded data Y[0:16] after encoding, and the binary sequence at the end of each row in Table 1-2 represents the encoding data segments SEG_enc which should be added for a corresponding situation. In the embodiment, when encoding, the original data X[0:15] can be divided into four data segments SEG1-SEG4 (b=4) of which the lengths are 4-bit, i.e. SEG1=X[0:3] (e.g. the first four bits of the original data X[0:15]), and so on SEG2=X[4:7], SEG3=X[8:11] and SEG4=X[12:15].

For example, in Tables 1-1 and 1-2, situation 1 represents that the conditions of all 0s or all 1s do not occur in each of the data segments SEG1-SEG4 of the original data X[0:15] (i.e. all the data segments SEG1-SEG4 are the uncompressible data segments SEG_us), such as X[0:15]={1011001010100110}, and SEG1-SEG4={1011}, {0010}, {1010} and {0110}. In such a situation, when encoding, the encoding data segment SEG_enc={0} of one additional bit can be directly added behind the original data X[0:15] without compressing the original data X[0:15], to indicate that there is no compressed data segment SEG_cs′ in the original data X[0:15], and generate the encoded data Y[0:16]={X[0:15], 0}={10110010101001100}.

On the other hand, in situation 4 of Tables 1-1 and 1-2, the data of all 0s or all 1s occur in the data segment SEG2 in the original data X[0:15] (i.e. the original data X[0:15] includes one compressible data segment SEG_cs), such as the original data X[0:15]={1011000010100110}, and the data segments SEG1-SEG4={1011}, {0000}, {1010} and {0110}. Since the contents in the data segment SEG2 are all 0s, the data segment SEG2 is the compressible data segment SEG_cs, and the data segments SEG1, SEG3 and SEG4 of the other data segments are uncompressible data segments SEG_us. Therefore, when encoding, the data segment SEG2={d4, d5, d6, d7} can be compressed into a compressed data segment SEG2′={d4}={0} of which the length is 1-bit (c=1), to replace the data segment SEG2 composed of repeated contents. As a result, the encoded data Y[0:16] still has the space of 4 bits (i.e. Y[13:16]) which can be utilized for the encoding data segment SEG_enc after the data segments SEG1, SEG2′, SEG3 and SEG4 are sequentially combined. In the embodiment, the encoding data segment SEG_enc can be set as {0011}, to indicate that the encoded data Y[0:16] includes one compressed data segment SEG_cs′ which is a second segment (i.e. the data segment SEG2) of the four data segments SEG1-SEG4. Therefore, the encoded data Y[0:16]={10110101001100011} is obtained after the original data X[0:15]={1011000010100110} be encoded.

On the other hand, as shown in situation 10 of Tables 1-1 and 1-2, the original data X[0:15] may include two data segments SEG2 and SEG3 which are composed of all 0s or all 1s (i.e. the original data X[0:15] includes two compressible data segments SEG_cs), such as the original data X[0:15]={1011000011110110}, and the data segments SEG1-SEG4={1011}, {0000}, {1111} and {0110}. Since the contents in the data segments SEG2 and SEG3 are all 0s or 1s, the data segments SEG2 and SEG3 are the compressible data segments SEG_cs, and the data segments SEG1 and SEG4 are uncompressible data segments SEG_us. Therefore, when encoding, the data segment SEG3={d8, d9, d10, d11} can be compressed into a compressed data segment SEG3′={d8}={1} of which the length is 1-bit, and the data segment SEG2={d4, d5, d6, d7} can be compressed into the compressed data segment SEG2′={d4, d4′}={01} of which the length is 2-bit (c=2). A complement of d4, i.e., d4′, is inserted to avoid the condition of 8 CIDs (e.g. SEG1={1000}, SEG2′={0}, SEG3′={0} and SEG4={0001}). As a result, the encoded data Y[0:16] still has the space of 6 bits (i.e. Y[11:16]) can be utilized for the encoding data segment SEG_enc after the data segments SEG1, SEG2′, SEG3′ and SEG4 are sequentially combined. In the embodiment, the encoding data segment SEG_enc can be set as {101001}, to indicate that the encoded data Y[0:16] includes two compressed data segments which are the second and third segments of the four data segments SEG1-SEG4.

In addition, please refer to situation 2 of Tables 1-1 and 1-2. When encoding, other special cases which may have more than 7 CIDs should also be considered for a setting of the encoding data segment SEG_enc. For example, considering the original data X[0:15]={0001001010101000} wherein all the four data segments SEG1-SEG4={0001}, {0010, {1010} and {1000} are uncompressible data segments. If the encoding data segment is set as SEGenc=[0], the last four bits of the encoded data Y[0:16] after encoding are Y[13:16]={0000}. Then, if a first data before next encoding is X[0:15]={0000000110111010} (situation 3 of the encoding Tables), a second data after encoding is Y[0:16]={00001101110100001}, and the four codes in the front of Y[0:16] are Y[0:3]={0000}. Therefore, the situation of 8 CIDs (CID=8) occur after combining two encoded second data. In the aforementioned situation, the last four codes Y[13:16]={0000} of the encoded data Y[0:16] after encoding the original data X[0:15] with four uncompressible data segments can be replaced with another specific sequence, such as {1001} (situation 2 of Tables 1-1 and 1-2).

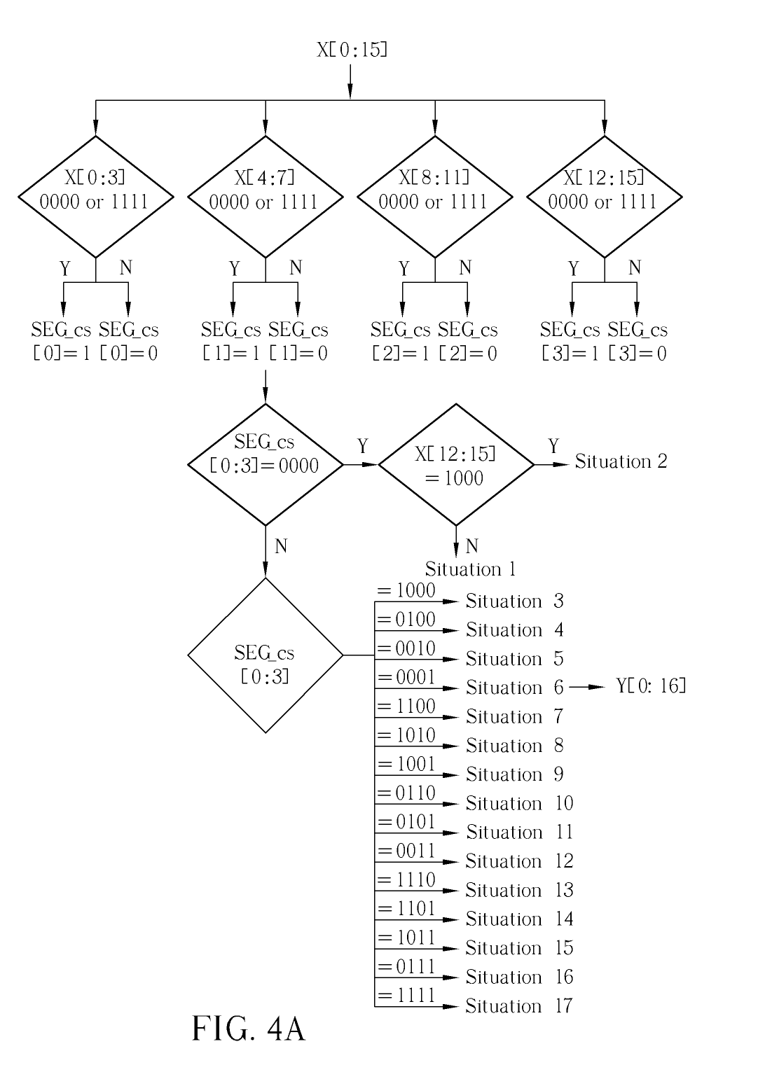

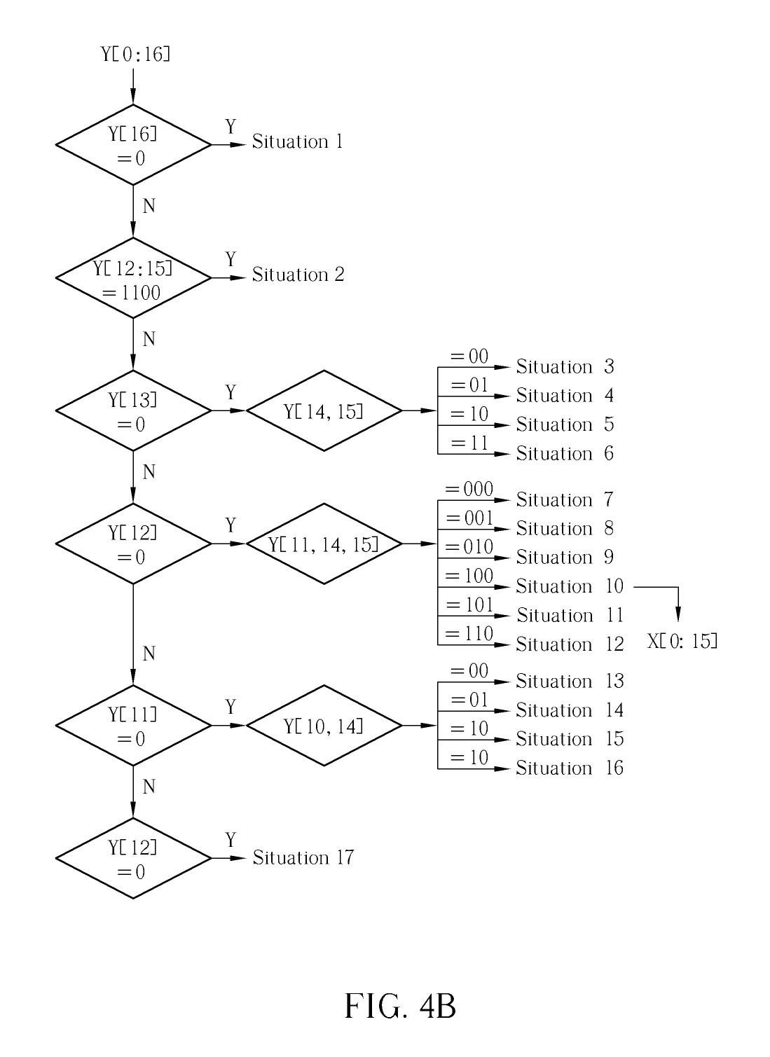

In detail, FIG. 4A and FIG. 4B are detailed processes of encoding and decoding of the 16-bit/17-bit (16B/17B) encoding method shown in Tables 1-1 and 1-2. As shown in FIG. 4A, whether the data segments SEG1-SEG4 are the compressible data segments SEG_cs are determined first, respectively, after the original data X[0:15] is received, and a determination result can be denoted as SEG_cs[0:3]. Then, SEG_cs[0:3]={0000} means that X[0:15] does not have compressible data segments, which corresponds to situation 1 or 2 of Tables 1-1 and 1-2. Then, whether SEG4=X[12:15] is complied with the aforementioned special data segment {1000} causing CID=8 can be further determined. If yes, encoding is performed according to situation 2 of Tables 1-1 and 1-2; otherwise, this situation corresponds to situation 1. Then, if SEG_cs[0:3] are not all 0s (representing having at least one compressible data segment), the rest 15 situations which are respectively corresponding to situation 3 to situation 17 in Tables 1-1 and 1-2 can be further determined according to SEG_cs[0:3]. In detail, if SEG_cs[0:3] only includes one “1” value (such as {1000}, {0100}, {0010} or {0001}), then SEG_cs[0:3] corresponds to situations 3-6 of Tables 1-1 and 1-2. If SEG_cs[0:3] includes two “1” values (such as {1100}, {1010}, {1001}, {0110}, {0101} or {0011}), then SEG_cs[0:3] corresponds to situations 7-12 of Tables 1-1 and 1-2. If SEG_cs[0:3] includes three “1” values ({1110}, {1101}, {1011} or {0111}), then SEG_cs[0:3] corresponds to situations 13-16 of Tables 1-1 and 1-2. Finally, if SEG_cs[0:3] are all 1s, then SEG_cs[0:3] corresponds to situation 17 of Tables 1-1 and 1-2. For example, if X[0:15]={0000000110111111} is received, SEG_cs[0:3]={1001} which corresponds to situation 9 of Tables 1-1 and 1-2 and the encoded data Y[0:16]={01000110111001101} are obtained.

Then, as shown in FIG. 4B, when decoding, the last bit Y[16] can be extracted first after the encoded data Y[0:16] a is received. If Y[16]=0, then the encoded data Y[0:16] does not include the compressed data segments, and corresponds to situation 1 of Tables 1-1 and 1-2. If Y[16]=1, then Y[12:15] is further extracted to determine whether the encoded data Y[0:16] is the special situation 2 of Tables 1-1 and 1-2. If Y[12:15] complies with the special segment {1100}, decoding and restoring are performed according to the special situation 2. Otherwise, each bit of Y[10:13] are further compared sequentially, to determine an amount and positions of the compressed data segments in the encoded data Y[0:16]. If Y[13]=0, the encoded data Y[0:16] only includes one compressible data segment, and can be further determined to which one of situations 3-6 of Tables 1-1 and 1-2 it corresponds, according to Y[14, 15]. Then, if Y[13]=1 and Y[12]=0, the encoded data Y[0:16] includes two compressible data segments, and can be further determined to which one of situations 7-12 of Tables 1-1 and 1-2 it corresponds, according to Y[11, 14, 15]. If Y[12, 13]={11} and Y[11]=0, the encoded data Y[0:16] includes three compressible data segments, and can be further determined to which one of situations 13-16 of Tables 1-1 and 1-2 it corresponds, according to Y[10, 14]. Finally, if Y[11:13]={111} and Y[10]=0, four segments SEG1-SEG4 of the original data X[0:15] are compressible data segments, and the encoded data Y[0:16] corresponds to situation 17 of Tables 1-1 and 1-2. For example, if Y[0:16]={01101010110011011} is received, then Y[16]=1, Y[12, 13]={11}, Y[11]=0 and Y[12:15] which is not equal to {1100} (not situation 2) can be determined, and the encoded data Y[0:16] corresponds to one of situations 13-16 of Tables 1-1 and 1-2. Since Y[10, 14]={00} corresponds to situation 13 in Tables 1-1 and 1-2, the original data X[0:15] should be restored to {0000111111111011}.

However, the aforementioned 16B/17B encoding method is only one embodiment of the present invention. In practice, the encoding process 10 and the decoding process 20 of the present invention can be used for encoding and decoding of data with different lengths. Please refer to Table 2, which is an encoding table of a 12-bit/13-bit (12B/13B) encoding method according to an embodiment of the present invention. The 12B/13B encoding method shown in Table 2 only adds one additional bit in the 12-bit data for performing encoding, and thus the overhead is only 1/13=7.7% of the encoded data Y[0:13] and only at most 6 CIDs (CID=6) of 0s or 1s are possible.

TABLE 2

| Situation | Y0 | Y1 | Y2 | Y3 | Y4 | Y5 | Y6 | Y7 | Y8 | Y9 | Y10 | Y11 | Y12 |
|---|---|---|---|---|---|---|---|---|---|---|---|---|---|
| 1 | d0 | d1 | d2 | d3 | d4 | d5 | d6 | d7 | d8 | d9 | d10 | d11 | 0 |
| 2 | d0 | d1 | d2 | d3 | d4 | d5 | d6 | d7 | 1 | 0 | 1 | 1 | 1 |
| 3 | d0 | d4 | d5 | d6 | d7 | d8 | d9 | d10 | d11 | 0 | 0 | 1 | 1 |
| 4 | d0 | d1 | d2 | d3 | d4 | d4′ | d8 | d9 | d10 | d11 | 0 | 0 | 1 |
| 5 | d0 | d1 | d2 | d3 | d4 | d5 | d6 | d7 | d8 | 0 | 1 | 0 | 1 |
| 6 | d0 | d4 | d4′ | d8 | d9 | d10 | d11 | 1 | 0 | 1 | 0 | 1 | 1 |
| 7 | d0 | d0′ | d4 | d5 | d6 | d7 | d8 | 1 | 0 | 1 | 1 | 0 | 1 |
| 8 | d0 | d1 | d2 | d3 | d4 | d4′ | d8 | 0 | 0 | 1 | 0 | 1 | 1 |
| 9 | d0 | d0′ | d4 | d4′ | d8 | d8′ | 1 | 0 | 1 | 1 | 0 | 1 | 1 |

In the 16B/17B encoding method and the 12B/13B encoding method of the aforementioned embodiment, the data are first grouped into a plurality of data segments (e.g. the data segments of 4-bit) of which the lengths are the same, but can also be alternated according to different applications. Please refer to Tables 3-1 and 3-2, which are encoding tables of a 24-bit/25-bit (24B/25B) encoding method according to an embodiment of the present invention. As shown in Tables 3-1 and 3-2, in the embodiment, the encoded data X[0:23] are divided according to a dividing method of 4, 5, 5, 5 and 5 bits first, i.e. the encoded data X[0:23] are divided into five data segments SEG1-SEG5, wherein SEG1=X[0:3], SEG2=X[4:8], SEG3=X[9:13], SEG4=X[14:18] and SEG5=[19:23]. The 24B/24B encoding method shown in Tables 3-1 and 3-2 only adds one additional bit in the data of the 24-bit for performing encoding, and thus the overhead is only 1/25=4% and only at most 9 CIDs (CID=9) of 0s or 1s are possible.

TABLE 3-1

| Situation | Y0 | Y1 | Y2 | Y3 | Y4 | Y5 | Y6 | Y7 | Y8 | Y9 | Y10 | Y11 | Y12 |
|---|---|---|---|---|---|---|---|---|---|---|---|---|---|
| 1 | d0 | d1 | d2 | d3 | d4 | d5 | d6 | d7 | d8 | d9 | d10 | d11 | d12 |
| 2 | d0 | d1 | d2 | d3 | d4 | d5 | d6 | d7 | d8 | d9 | d10 | d11 | d12 |
| 3 | d0 | d4 | d5 | d6 | d7 | d8 | d9 | d10 | d11 | d12 | d13 | d14 | d15 |
| 4 | d0 | d1 | d2 | d3 | d4 | d9 | d10 | d11 | d12 | d13 | d14 | d15 | d16 |
| 5 | d0 | d1 | d2 | d3 | d4 | d5 | d6 | d7 | d8 | d9 | d14 | d15 | d16 |
| 6 | d0 | d1 | d2 | d3 | d4 | d5 | d6 | d7 | d8 | d9 | d10 | d11 | d12 |
| 7 | d0 | d1 | d2 | d3 | d4 | d5 | d6 | d7 | d8 | d9 | d10 | d11 | d12 |
| 8 | d0 | d0′ | d4 | d9 | d10 | d11 | d12 | d13 | d14 | d15 | d16 | d17 | d18 |
| 9 | d0 | d4 | d5 | d6 | d7 | d8 | d9 | d14 | d15 | d16 | d17 | d18 | d19 |
| 10 | d0 | d4 | d5 | d6 | d7 | d8 | d9 | d10 | d11 | d12 | d13 | d14 | d19 |
| 11 | d0 | d4 | d5 | d6 | d7 | d8 | d9 | d10 | d11 | d12 | d13 | d14 | d15 |
| 12 | d0 | d1 | d2 | d3 | d4 | d4′ | d9 | d14 | d15 | d16 | d17 | d18 | d19 |
| 13 | d0 | d1 | d2 | d3 | d4 | d9 | d10 | d11 | d12 | d13 | d14 | d19 | d20 |
| 14 | d0 | d1 | d2 | d3 | d4 | d9 | d10 | d11 | d12 | d13 | d14 | d15 | d16 |
| 15 | d0 | d1 | d2 | d3 | d4 | d5 | d6 | d7 | d8 | d9 | d9′ | d14 | d19 |
| 16 | d0 | d1 | d2 | d3 | d4 | d5 | d6 | d7 | d8 | d9 | d14 | d15 | d16 |
| 17 | d0 | d1 | d2 | d3 | d4 | d5 | d6 | d7 | d8 | d9 | d10 | d11 | d12 |
| 18 | d0 | d0′ | d4 | d4′ | d9 | d9′ | d14 | d15 | d16 | d17 | d18 | d19 | d20 |
| 19 | d0 | d0′ | d4 | d4′ | d9 | d10 | d11 | d12 | d13 | d14 | d14′ | d19 | d20 |
| 20 | d0 | d0′ | d4 | d4′ | d9 | d10 | d11 | d12 | d13 | d14 | d15 | d16 | d17 |
| 21 | d0 | d0′ | d4 | d5 | d6 | d7 | d8 | d9 | d9′ | d14 | d14′ | d19 | d20 |
| 22 | d0 | d0′ | d4 | d5 | d6 | d7 | d8 | d9 | d9′ | d14 | d15 | d16 | d17 |
| 23 | d0 | d0′ | d4 | d5 | d6 | d7 | d8 | d9 | d10 | d11 | d12 | d13 | d14 |
| 24 | d0 | d1 | d2 | d3 | d4 | d4′ | d9 | d9′ | d14 | d14′ | d19 | d20 | d21 |
| 25 | d0 | d1 | d2 | d3 | d4 | d4′ | d9 | d9′ | d14 | d15 | d16 | d17 | d18 |
| 26 | d0 | d1 | d2 | d3 | d4 | d4′ | d9 | d10 | d11 | d12 | d13 | d14 | d14′ |
| 27 | d0 | d1 | d2 | d3 | d4 | d5 | d6 | d7 | d8 | d9 | d9′ | d14 | d14′ |
| 28 | d0 | d0′ | d4 | d4′ | d9 | d9′ | d14 | d14′ | d19 | d20 | d21 | d22 | d23 |
| 29 | d0 | d0′ | d4 | d4′ | d9 | d9′ | d14 | d15 | d16 | d17 | d18 | d19 | d19′ |
| 30 | d0 | d0′ | d4 | d4′ | d9 | d10 | d11 | d12 | d13 | d14 | d14′ | d19 | d19′ |
| 31 | d0 | d0′ | d4 | d5 | d6 | d7 | d8 | d9 | d9′ | d14 | d14′ | d19 | d19′ |
| 32 | d0 | d1 | d2 | d3 | d4 | d4′ | d9 | d9′ | d14 | d14′ | d19 | d19′ | 1 |
| 33 | d0 | d0′ | d4 | d4′ | d9 | d9′ | d14 | d14′ | d19 | d19′ | 0 | 1 | 0 |

TABLE 3-2

| Situation | Y13 | Y14 | Y15 | Y16 | Y17 | Y18 | Y19 | Y20 | Y21 | Y22 | Y23 | Y24 |
|---|---|---|---|---|---|---|---|---|---|---|---|---|
| 1 | d13 | d14 | d15 | d16 | d17 | d18 | d19 | d20 | d21 | d22 | d23 | 0 |
| 2 | d13 | d14 | d15 | d16 | d17 | d18 | 0 | 1 | 0 | 1 | 1 | 1 |
| 3 | d16 | d17 | d18 | d19 | d20 | d21 | d22 | d23 | 1 | 0 | 0 | 1 |
| 4 | d17 | d18 | d19 | d20 | d21 | d22 | d23 | 1 | 0 | 0 | 1 | 1 |
| 5 | d17 | d18 | d19 | d20 | d21 | d22 | d23 | 1 | 0 | 1 | 0 | 1 |
| 6 | d13 | d14 | d19 | d20 | d21 | d22 | d23 | 0 | 0 | 0 | 1 | 1 |
| 7 | d13 | d14 | d15 | d16 | d17 | d18 | d19 | 0 | 0 | 1 | 0 | 1 |
| 8 | d19 | d20 | d21 | d22 | d23 | 1 | 0 | 1 | 0 | 0 | 0 | 1 |
| 9 | d20 | d21 | d22 | d23 | 0 | 1 | 0 | 1 | 1 | 1 | 0 | 1 |
| 10 | d20 | d21 | d22 | d23 | 0 | 1 | 0 | 0 | 1 | 0 | 1 | 1 |
| 11 | d16 | d17 | d18 | d19 | 0 | 1 | 0 | 0 | 1 | 1 | 0 | 1 |
| 12 | d20 | d21 | d22 | d23 | 1 | 0 | 0 | 1 | 1 | 0 | 1 | 1 |
| 13 | d21 | d22 | d23 | 0 | 1 | 0 | 0 | 1 | 1 | 1 | 0 | 1 |
| 14 | d17 | d18 | d19 | 0 | 1 | 0 | 0 | 0 | 1 | 0 | 1 | 1 |
| 15 | d20 | d21 | d22 | d23 | 1 | 0 | 0 | 0 | 1 | 1 | 0 | 1 |
| 16 | d17 | d18 | d19 | 0 | 1 | 1 | 0 | 1 | 1 | 0 | 1 | 1 |
| 17 | d13 | d14 | d19 | 0 | 1 | 1 | 0 | 1 | 1 | 1 | 0 | 1 |
| 18 | d21 | d22 | d23 | 0 | 0 | 1 | 1 | 0 | 1 | 0 | 1 | 1 |
| 19 | d21 | d22 | d23 | 0 | 0 | 1 | 1 | 0 | 1 | 1 | 0 | 1 |
| 20 | d18 | d19 | d19′ | 0 | 0 | 1 | 1 | 1 | 1 | 0 | 1 | 1 |
| 21 | d21 | d22 | d23 | 0 | 0 | 1 | 1 | 1 | 1 | 1 | 0 | 1 |
| 22 | d18 | d19 | d19′ | 0 | 1 | 0 | 1 | 0 | 1 | 0 | 1 | 1 |
| 23 | d14′ | d19 | d19′ | 0 | 1 | 0 | 1 | 0 | 1 | 1 | 0 | 1 |
| 24 | d22 | d23 | 1 | 0 | 1 | 0 | 1 | 1 | 1 | 0 | 1 | 1 |
| 25 | d19 | d19′ | 1 | 0 | 1 | 0 | 1 | 1 | 1 | 1 | 0 | 1 |
| 26 | d19 | d19′ | 1 | 0 | 1 | 1 | 1 | 0 | 1 | 0 | 1 | 1 |
| 27 | d19 | d19′ | 1 | 0 | 1 | 1 | 1 | 0 | 1 | 1 | 0 | 1 |
| 28 | 0 | 1 | 0 | 1 | 0 | 0 | 1 | 0 | 1 | 0 | 1 | 1 |
| 29 | 0 | 1 | 0 | 1 | 0 | 0 | 1 | 0 | 1 | 1 | 0 | 1 |
| 30 | 0 | 1 | 0 | 1 | 0 | 0 | 1 | 1 | 1 | 0 | 1 | 1 |
| 31 | 0 | 1 | 0 | 1 | 0 | 0 | 1 | 1 | 1 | 1 | 0 | 1 |
| 32 | 0 | 1 | 0 | 1 | 0 | 1 | 1 | 0 | 1 | 0 | 1 | 1 |
| 33 | 1 | 1 | 0 | 1 | 0 | 1 | 1 | 0 | 1 | 1 | 0 | 1 |

Furthermore, Table 4 is a comparison diagram of different encoding methods of the embodiment of the present invention with the prior art. As shown in Table 4, although a 8B/10B encoding method of the prior art only includes at most 5 CIDs (CID=5), but the rate of overhead is up to 20%, and although the rate of overhead is only 3% in a 64B/65B encoding method of the prior art, but the number of CIDs is up to 65. In comparison, in different embodiments of the present invention, the encoding methods for data with different lengths can be realized by adding only one additional bit, and the rate of overhead and the number of CIDs are both moderate. For example, the overhead caused by the 24B/25B, the 12B/13B and the 16B/17B encoding methods of the embodiment of the present invention are much lower than the 8B/10B encoding method of the prior art of which the rate of overhead is 20%, and the longest CIDs of the embodiment of the present invention are much lower than the 64B/65B encoding method of the prior art of which the number of longest CIDs is 65.

TABLE 4

| Encoding | | |
|---|---|---|
| method | Overhead | Longest CID |
| prior art | 20% | 5 |
| 8B/10B | | |
| prior art | 3% | 65 |
| 64B/66B | | |
| embodiment | 5.9% | 7 |
| 16B/17B | | |
| embodiment | 7.7% | 6 |
| 12B/13B | | |
| embodiment | 4% | 9 |
| 24B/25B | | |

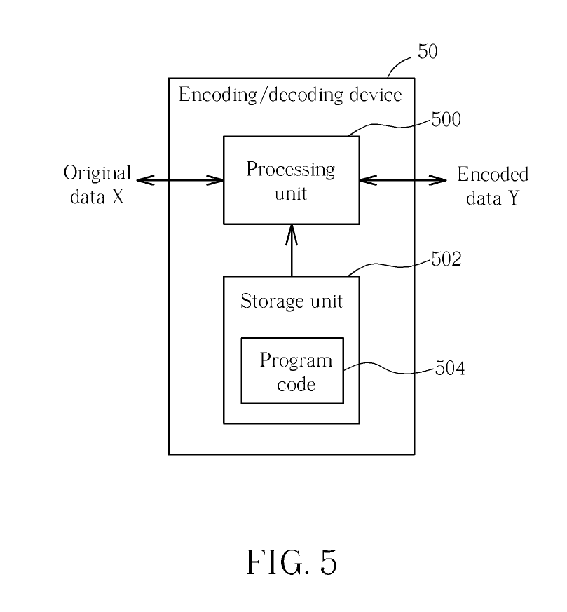

Realizations of the encoding process 10 and the decoding process 20 can be referred to FIG. 5, which is a schematic diagram of an encoding/decoding device 50 according to an embodiment of the present invention. The encoding/decoding device 50 includes a processing unit 500, a storage unit 502 and a program code 504. The program code 504 is stored in the storage unit 502, for realizing the encoding process 10 and the decoding process 20 to indicate the processing unit 500 to execute functions and related alterations corresponding to the encoding process 10 and the decoding process 20. For example, the processing unit 500 can encode the original data X received by the encoding/decoding device 50 to generate the encoded data Y, or decode the encoded data Y received by the encoding/decoding device 50 to restore to the original data X. Skills of realizing the encoding process 10 and the decoding process 20 via the program code 504 are known to those skilled in the art, and are not narrated hereinafter. Noticeably, the processing unit 500 and the storage unit 502 of the encoding/decoding device 50 can be realized via methods of hardware, software and firmware, etc., and are not limited. The encoding/decoding device 50 can be used in various communication devices or other different electronic products.

Note that, the main spirit of the present invention is to utilize the data space saved from compressing the identical values in the original data, and perform encoding with fewer additional bits, so as to reduce overhead of transmission, and also reduce the number of the bits of consecutive 1s or 0s, to improve efficiency of the transmission. Those skilled in the art may make alterations or modifications according to the concept of the present invention, and is not limited. For example, the method of dividing the original data is not limited to an equal division, and division length is also not limited. If there are a large number of consecutive digits in the original data, then the division length can be increased, to achieve preferably space saving. Contents of the encoding data segments can also be arranged according to different methods; however, the prerequisite is that the condition of long consecutive identical digits caused by combining two adjacent encoded data should be taken into consideration. In addition, in other embodiments, multiple compressed segments are also not limited to be divided by using complement data values.

To sum up, comparing with the conventional encoding method with more additional bits waste or long consecutive identical digits for data transmission, causing difficulties of restoring clocks or data when decoding, the encoding method of the present invention can effectively utilize a data space saved from compressing the identical digits in the original data, and perform encoding with fewer additional bits, so as to reduce overhead of transmission, and also reduce the number of the bits of consecutive 1s or 0s. As a result, the transmission is more efficient and the system requirements of the clocks and data recovery circuit in the receiving terminal are relaxed.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An encoding method, comprising:
receiving a first data with a first length;
dividing the first data into a plurality of data segments with a first specific length;
obtaining at least one compressible data segment composed of identical data values if it exists and at least one uncompressible data segment composed of non-identical data values if it exists from the plurality of data segments;
compressing the at least one compressible data segment to obtain at least one compressed data segment with a second specific length if it exists;
generating an encoding data segment according to quantity and position of the at least one compressed data segment; and
combining the compressed data segment, the uncompressible data segment and the encoding data segment to generate a second data with a second length;
wherein the second specific length is shorter than the first specific length.

2. The encoding method of claim 1, wherein the step of compressing the at least one compressible data segment to obtain the at least one compressed data segment with the second specific length if it exists comprises:
compressing the identical data values with the first specific length in the at least one compressible data segment into data values of which a length is the second specific length or a complement of the data values respectively, to obtain the at least one compressed data segment if it exists.

3. The encoding method of claim 1, wherein the step of compressing the at least one compressible data segment to obtain the at least one compressed data segment with the second specific length if it exists comprises:
compressing the identical data values with the first specific length in the at least one compressible data segment into the data values of which a length is the second specific length minus one respectively, and adding a complement data value of the data values behind the data values, to obtain the at least one compressed data segment if it exists.

4. The encoding method of claim 1, wherein a data length of the encoding data segment is equal to a sum of at least one additional bit and the first length minus a total data length of the at least one compressible data segment and the at least one uncompressible data segment.

5. The encoding method of claim 1, wherein the step of combining the at least one compressed data segment if it exists, the at least one uncompressible data segment if it exists and the encoding data segment to generate the second data comprises:
replacing consecutive identical data values with another specific data segment, when the consecutive identical data values appear on an end of data over the first specific length obtained by combining the at least one compressed data segment, the at least one uncompressible data segment and the encoding data segment, to generate the second data.

6. An encoding device, comprising:
a processor; and
a storage device, storing a program code, the program code is utilized for indicating the processor to execute the following steps:
receiving a first data with a first length;
dividing the first data into a plurality of data segments with a first specific length;
obtaining at least one compressible data segment composed of identical data values if it exists and at least one uncompressible data segment composed of non-identical data values if it exists from the plurality of data segments;
compressing the at least one compressible data segment to obtain at least one compressed data segment with a second specific length if it exists;
generating an encoding data segment according to quantity and position of the at least one compressed data segment; and
combining the at least one compressed data segment, the at least one uncompressible data segment and the encoding data segment to generate a second data with a second length;
wherein the second specific length is shorter than the first specific length.

7. The encoding device of claim 6, wherein the processor compresses the identical data values with the first specific length in the at least one compressible data segment into data values of which a length is the second specific length or a complement of the data values respectively, to obtain the at least one compressed data segment if it exists.

8. The encoding device of claim 6, wherein the processor compresses the identical data values with the first specific length in the at least one compressible data segment into the data values of which a length is the second specific length minus one respectively, and adding a complement data value of the data values behind the data values, to obtain the at least one compressed data segment if it exists.

9. The encoding device of claim 6, wherein a data length of the encoding data segment is equal to a sum of an additional bit and the first length minus a total data length of the at least one compressible data segment and the at least one uncompressible data segment.

10. The encoding device of claim 6, wherein the processor replaces consecutive identical data values with another specific data segment, when the consecutive identical data values appear on an end of data over the first specific length obtained after the processor combines the at least one compressed data segment, the at least one uncompressible data segment and the encoding data segment, to generate the second data.

11. A decoding method, comprising:
receiving a second data with a second length;
obtaining an encoding data segment of the second data;
obtaining at least one compressed data segment with a second specific length if it exists and at least one uncompressible data segment with a first specific length if it exists from the second data according to the encoding data segment;
restoring the at least one compressed data segment to at least one compressible data segment with the first specific length and identical data values if it exists; and
combining the at least one compressible data segment if it exists and the at least one uncompressible data segment if it exists with the first specific length, to generate a first data with a first length;
wherein the second specific length is shorter than the first specific length.

12. The decoding method of claim 11, wherein the step of restoring the at least one compressed data segment to the at least one compressible data segment with the first specific length if it exists and the identical data values comprises:
obtaining a data value of each compressed data segment of the at least one compressed data segment respectively, and consecutive data values with the first specific length are used for composing the at least one compressible data segment, wherein each of the consecutive data values is equal to the data value or a complement of the data value.

13. The decoding method of claim 11, wherein the step of restoring the at least one compressed data segment to the at least one compressible data segment with the first specific length if it exists and the identical data values comprises:
obtaining a data value and a complement data value of each compressed data segment of the at least one compressed data segment respectively, and consecutive data values with the first specific length are used for composing the at least one compressible data segment, wherein each of the consecutive data values is equal to the data value or a complement of the data values.

14. The decoding method of claim 11, wherein the encoding data segment is utilized for indicating the quantity and position of the at least one compressed data segment in the first data, and a data length of the encoding data segment is equal to a sum of an additional bit and the first length minus a total data length of the at least one compressible data segment and the at least one uncompressible data segment.

15. The decoding method of claim 11, wherein the step of receiving the second data with the second length comprises:
replacing a specific data segment with a data segment of consecutive identical data values with the first specific length, when an end of the second data is the specific data segment.

16. A decoding device, comprising:
a processor; and
a storage device, storing a program code, the program code is utilized for indicating the processor to execute the following steps:
receiving a second data with a second length;
obtaining an encoding data segment of the second data;
obtaining at least one compressed data segment with a second specific length if it exists and at least one uncompressible data segment with a first specific length if it exists from the second data according to the encoding data segment;
restoring the at least one compressed data segment to at least one compressible data segment with the first specific length and identical data values if it exists; and
combining the at least one compressible data segment and the at least one uncompressible data segment with the first specific length, to generate a first data with a first length;
wherein the second specific length is shorter than the first specific length.

17. The decoding device of claim 16, wherein the processor obtains a data value of each compressed data segment of the at least one compressed data segment if it exists respectively, and consecutive data values with the first specific length are used for composing the at least one compressible data segment, wherein each of the consecutive data values is equal to the data value or a complement of the data values.

18. The decoding device of claim 16, wherein the processor obtains a data value and a complement data value of each compressed data segment of the at least one compressed data segment if it exists respectively, and consecutive data values with the first specific length are used for composing the at least one compressible data segment, wherein each of the consecutive data values is equal to the data value or a complement of the data values.

19. The decoding device of claim 16, wherein the encoding data segment is utilized for indicating the quantity and position of the at least one compressed data segment in the first data, and a data length of the encoding data segment is equal to a sum of an additional bit and the first length minus a total data length of the at least one compressible data segment and the at least one uncompressible data segment.

20. The decoding device of claim 16, wherein the processor replaces a specific data segment with a data segment of consecutive identical data values with the first specific length, when an end of the second data is the specific data segment.
